(19) United States
(12) Patent Application Publication
(10) Pub. No.: US 2008/0297136 A1
(43) Pub. Date: Dec. 4, 2008

(54) SYSTEM AND METHOD TO DETECT, IN A VEHICLE, BLOCKAGE OF AN AIRFLOW PASSAGE TO A POWER STORAGE UNIT

(75) Inventors: Scott Howard Gaboury, Ann Arbor, MI (US); Lixin Situ, Canton, MI (US); William Paul Perkins, Dearborn, MI (US); Steven A. Daleiden, Milan, MI (US)

Correspondence Address: BROOKS KUSHMAN P.C./FGTL, 1000 TOWN CENTER, 22ND FLOOR, SOUTHFIELD, MI, 48075-1238, US

(73) Assignee: FORD GLOBAL TECHNOLOGIES, LLC, Dearborn, MI (US)

(21) Appl. No.: 11/755,309

(22) Filed: May 30, 2007

(51) Int. Cl. G01R 19/00; B60H 1/24

(52) U.S. Cl. 324/76.11; 454/69

(57) ABSTRACT

A driver of a vehicle is alerted if an air passage from an air source to a battery becomes blocked. The determination as to whether the air passage is blocked may be based on the temperature of the battery, the airflow through the air passage, and the power to a fan used to move air through the air passage.

### BACKGROUND OF THE INVENTION

1. Field of the Invention

The invention relates to systems and methods to detect, in vehicles, blockages of airflow passages to power storage units.

2. Discussion

Battery systems used to store electrical energy in a Hybrid Electric Vehicle (HEV) may produce heat when storing or releasing energy. Thermal management of battery systems may improve battery performance and extend battery life.

Some HEV battery systems are cooled by separate cooling systems while others are cooled by cabin air flow.

### SUMMARY

Embodiments of the invention may take the form of a method for determining, in a vehicle, if an airflow passage is at least partially blocked. The method includes determining a power to a fan, determining a temperature of a power storage unit, and determining if the airflow passage is at least partially blocked based on the power to the fan and the temperature of the power storage unit. The method also includes indicating that the airflow passage is at least partially blocked if it is determined that the airflow passage is at least partially blocked.

Embodiments of the invention may take the form of a method for determining, in a vehicle, if an airflow passage is at least partially blocked. The method includes determining a power to a fan, determining at least one of an air flow and an air pressure in the airflow passage, and determining if the airflow passage is at least partially blocked based on the power to the fan and the at least one of air flow and air pressure in the airflow passage. The method also includes indicating that the airflow passage is at least partially blocked if it is determined that the airflow passage is at least partially blocked.

Embodiments of the invention may take the form of a method for determining, in a vehicle, if an airflow passage is at least partially blocked. The method includes determining an on/off state of a fan, determining a temperature of air in the airflow passage, and determining a temperature of a power storage unit. The method also includes determining if the airflow passage is at least partially blocked based on the on/off state of the fan, the temperature of the air in the airflow passage, and the temperature of the power storage unit. The method further includes indicating that the airflow passage is at least partially blocked if it is determined that the airflow passage is at least partially blocked.

While exemplary embodiments in accordance with the invention are illustrated and disclosed, such disclosure should not be construed to limit the claims. It is anticipated that various modifications and alternative designs may be made without departing from the scope of the invention.

### BRIEF DESCRIPTION OF THE DRAWINGS

FIG. 1 is a perspective view of a vehicle seat and traction battery showing air, as indicated by arrow, entering an opening at a foot of the seat, flowing underneath the seat to the traction battery, to cool the traction battery, and exiting the traction battery.

FIG. 2 is another perspective view of the vehicle seat and traction battery of FIG. 1 showing the opening at the foot of the seat partially obstructed by a brief case and a reduced amount air, relative to FIG. 1, entering the opening, flowing underneath the seat to the traction battery, to cool the traction battery, and exiting the traction battery.

FIG. 3 is a side, schematic view of the vehicle seat and traction battery of FIG. 1 and shows a fan, temperature sensor, and display in communication with a controller.

FIG. 4 is a side, schematic view of an alternative embodiment of the vehicle seat and traction battery of FIG. 1 and shows a fan, airflow sensor, and display in communication with a controller.

FIG. 5 is a side, schematic view of another alternative embodiment of the vehicle seat and traction battery of FIG. 1 and shows a fan, two temperature sensors, and a display in communication with a controller.

FIG. 6A is a flow chart of a method for determining if the opening at the foot of the seat of FIG. 1 is obstructed.

FIG. 6B is flow chart of an alternative portion of the method of FIG. 6A.

FIG. 6C is another flow chart of an alternative portion of the method of FIG. 6A.

FIG. 7A is a flow chart of a method for determining if the opening at the foot of the seat of FIG. 2 is obstructed.

FIG. 7B is a flow chart of an alternative portion of the method of FIG. 7A.

FIG. 7C is another flow chart of an alternative portion of the method of FIG. 7A.

FIG. 8 is a flow chart of a method for determining if the opening at the foot of the seat of FIG. 3 is obstructed.

FIG. 9A is a flow chart of a method for determining if an air passage is at least partially blocked in accordance with an embodiment of the invention.

FIG. 9B is a flow chart of an alternative portion of the method of FIG. 9A.

FIG. 9C is another flow chart of an alternative portion of the method of FIG. 9A.

FIG. 10A is another flow chart of a method for determining if an air passage is at least partially blocked in accordance with an embodiment of the invention.

FIG. 10B is a flow chart of an alternative portion of the method of FIG. 10A.

FIG. 10C is another flow chart of an alternative portion of the method of FIG. 10A.

FIG. 11A is still another flow chart of a method for determining if an air passage is at least partially blocked in accordance with an embodiment of the invention.

FIG. 11B is a flow chart of an alternative portion of the method of FIG. 11A.

FIG. 11C is another flow chart of an alternative portion of the method of FIG. 11A.

FIG. 12A is still yet another flow chart of a method for determining if an air passage is at least partially blocked in accordance with an embodiment of the invention.

FIG. 12B is a flow chart of an alternative portion of the method of FIG. 12A.

FIG. 12C is another flow chart of an alternative portion of the method of FIG. 12A.

### DETAILED DESCRIPTION

Embodiments of the invention may predict air flow blockage in an air flow passage between the vehicle cabin and battery pack, or between the exterior of the vehicle and battery pack, by sensing the temperature of the cabin air and the temperatures inside the battery pack, particularly near the battery air inlet. Estimated cabin air temperature data may be available on the vehicle Controller Area Network from other subsystems in the vehicle.

Unblocked air passage performance profiles of typical temperature gradients with proper airflow may be developed through temperature testing at, for example, various cabin temperatures and battery states. Blocked air passage performance profiles may similarly be developed. With these profiles, a determination can be made, given, for example, certain temperature data, whether an air flow passage is blocked. For example, large differences between real time cabin temperatures and real time measured internal battery temperatures may indicate a blocked air passage. If a blockage is detected, a text message may be put onto the vehicle's message center requesting the driver to examine the air inlet area to remove any potential obstacles.

Embodiments of the invention may use an airflow sensor to measure whether a predetermined lower limit for required airflow is being exceeded. Readings from the sensor would be directed to a control module. The control module would sample the airflow sensor at a relatively low frequency, or possibly when battery temperature is rising or high.

Embodiments of the invention may employ a yes/no strategy with a timer and airflow sensor. A control system would sample airflow, determine whether the airflow is below a lower threshold, and then set a time that will direct when the airflow should be sampled again. If the airflow is, for example, near zero, the control system would send a text message to a display screen informing the driver of blocked battery ducting and requesting that the driver examine the duct inlet for obstacles.

Embodiments of the invention may measure mass airflow and store the actual number measured for comparison against a threshold to create a short-term performance history. This would enable detailed analysis and trouble shooting.

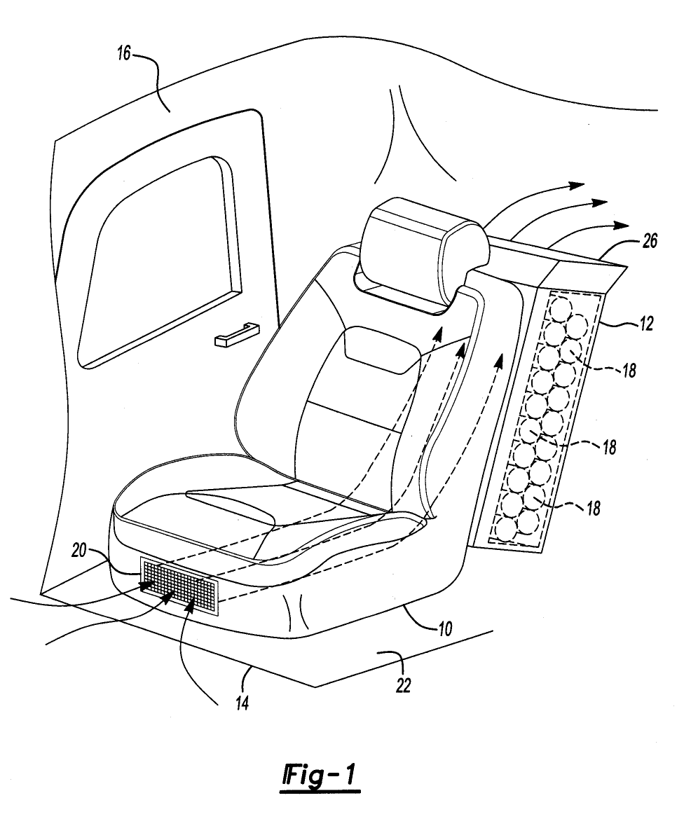

FIG. 1 is a perspective view of rear seat 10 and high voltage battery 12. Rear seat 10 is located within interior 14 of vehicle 16. High voltage battery 12 is located behind rear seat 10, e.g., in a trunk region of vehicle 16. High voltage battery 12, however, may be in any suitable location, e.g., center console, under seats, etc. High voltage battery 12 includes storage cells 18 which store energy that may be used to move vehicle 16.

Seat 10 includes opening 20 which allows air to flow underneath rear seat 10, e.g., between floor pan 22 and rear seat 10, to high voltage battery 12. The air cools storage cells 18 and then exits high voltage battery 12 into the trunk region of vehicle 16. In other embodiments, the air may exit high voltage battery 12 into, for example, vehicle 16.

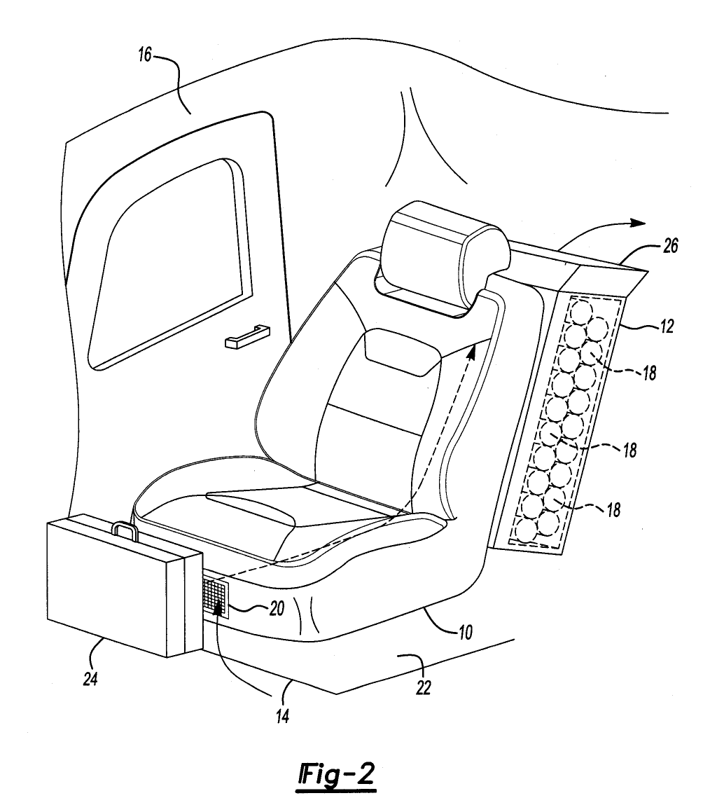

FIG. 2 is another perspective view of rear seat 10 and high voltage battery 12. In FIG. 2, briefcase 24 is partially blocking opening 20. As a result, a reduced amount of air flows through opening 20, underneath rear seat 10, and to high voltage battery 12. Storage cells 18 may thus experience a reduced amount of cooling.

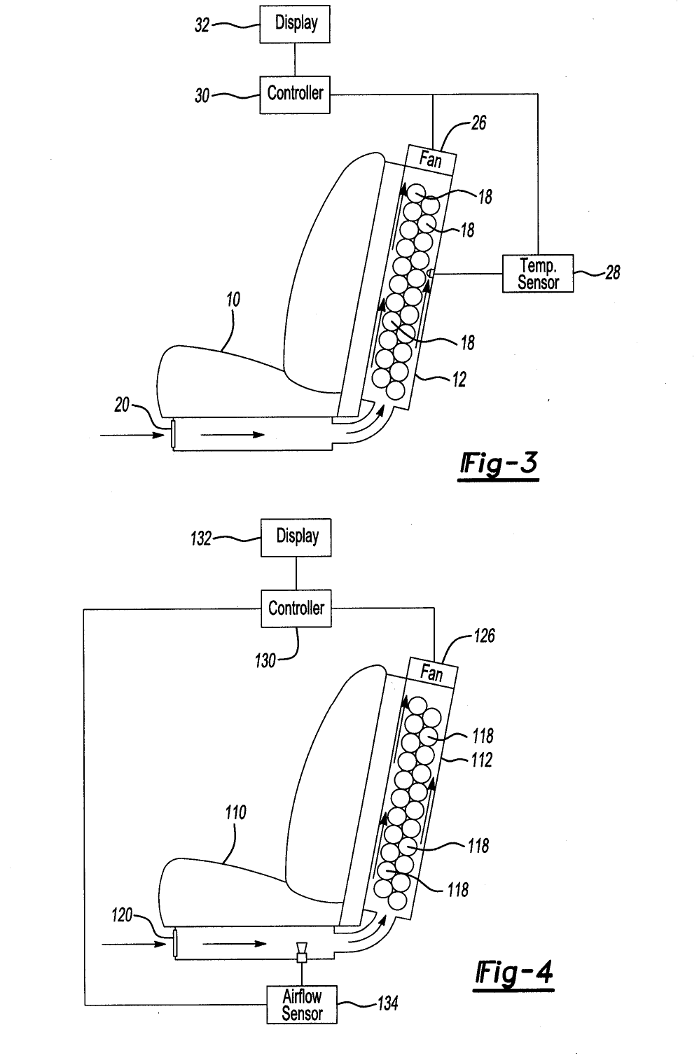

FIG. 3 is a side, schematic view of rear seat 10 and high voltage battery 12. Fan 26 pulls air into opening 20, underneath rear seat 10, and into high voltage battery 12. Temperature sensor 28 determines an average temperature of storage cells 18. Fan 26 and temperature sensor 28 are in communication with controller 30. Controller 30 thus can determine the amount of power delivered to fan 26 and is also informed of the average temperature of storage cells 18. If opening 20 is not blocked, the amount of power delivered to fan 26 generally corresponds to a drop in temperature of storage cells 18. If, however, opening 20 is partially or completely blocked, storage cells 18 may not experience a drop in temperature for a given power to fan 26. Controller 30 may thus determine, based on the power to fan 26 and the temperature of storage cells 18, whether opening 20 is partially or completely blocked. This determination may be implemented several ways. For example, for a given power to fan 26 controller 30 may determine if the temperature of storage cells 18 is changing, increasing, decreasing, and/or exceeding some threshold. Likewise, controller 30 may determine if a power to fan 26 is increasing, decreasing, and/or exceeding a threshold and compare that power with the temperature of storage cells 18. As explained above, thresholds may be determined through testing of blocked and unblocked systems.

If controller 30 determines that opening 20 is blocked, controller 30 notifies an occupant of vehicle 16 via display 32.

FIG. 4 is a side, schematic view of an alternative embodiment of rear seat 110 and high voltage battery 112. Numbered elements differing by factors of 100 have similar descriptions, e.g., controllers 30, 130 have similar descriptions. Airflow sensor 134 measures the flow rate of air under seat 110 and communicates that information to controller 130. In other embodiments, airflow sensor 134 measures air pressure and communicates that information to controller 130. Controller 130 uses airflow rate information received from airflow sensor 134 in combination with information concerning the power delivered to fan 126 to determine whether opening 120 is partially or completely blocked. For example, controller 130 may determine, for a given airflow rate, whether the power to fan 126 is increasing or exceeding some threshold. If the airflow rate is low yet the power to fan 126 is increasing, opening 20 may be blocked. Controller 130 may also determine, for a given power to fan 126, if the airflow rate is decreasing and/or less than some threshold. If the power to fan 126 is high yet the airflow rate is decreasing and/or less than the threshold, opening 20 may be blocked.

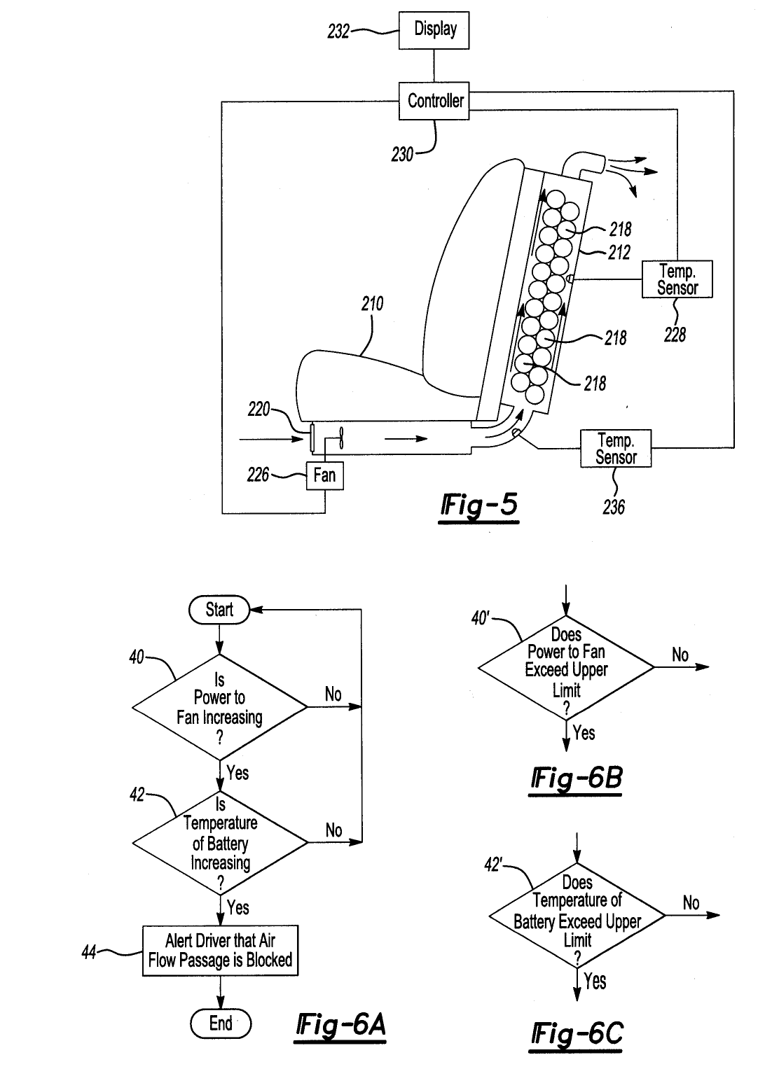

FIG. 5 is a side, schematic view of another alternative embodiment of rear seat 210 and high voltage battery 212. Temperature sensor 236 measures the temperature of air flowing underneath rear seat 210 prior to entering high voltage battery 212. Controller 230 uses information received from fan 226, temperature sensor 228, and temperature sensor 236 to determine whether opening 220 is partially or completely blocked. For example, if controller 230 determines that fan 226 is on and the temperature of storage cells 218 is changing, e.g., increasing, and the temperature of air as measured by temperature sensor 236 is less than some threshold, controller 230 may determine that opening 220 is at least partially blocked.

FIG. 6A is a flow chart of a method for determining whether the airflow passage of FIG. 1 is blocked. At 40, controller 30 determines whether the power to fan 26 is increasing. If no, the method loops back to Start. If yes, at 42, controller 30 determines whether the temperature of high voltage battery 12 is increasing. If no, the method loops back to Start. If yes, at 44, controller 30 alerts the driver that the airflow passage is blocked via display 32.

FIG. 6B is flow chart of an alternative step of the method of FIG. 6A. At 40′, controller 30 determines whether the power to fan 26 exceeds an upper limit, e.g., 50 W. If no, the method loops back to Start. If yes, the method continues to 42.

FIG. 6C is another flow chart of an alternative step of the method of FIG. 6A. At 42′, controller 30 determines whether the temperature of high voltage battery 12 exceeds an upper limit, e.g., 40° C. for a Lithium Ion battery. If no, the method loops back to Start. If yes, the method continues to 44.

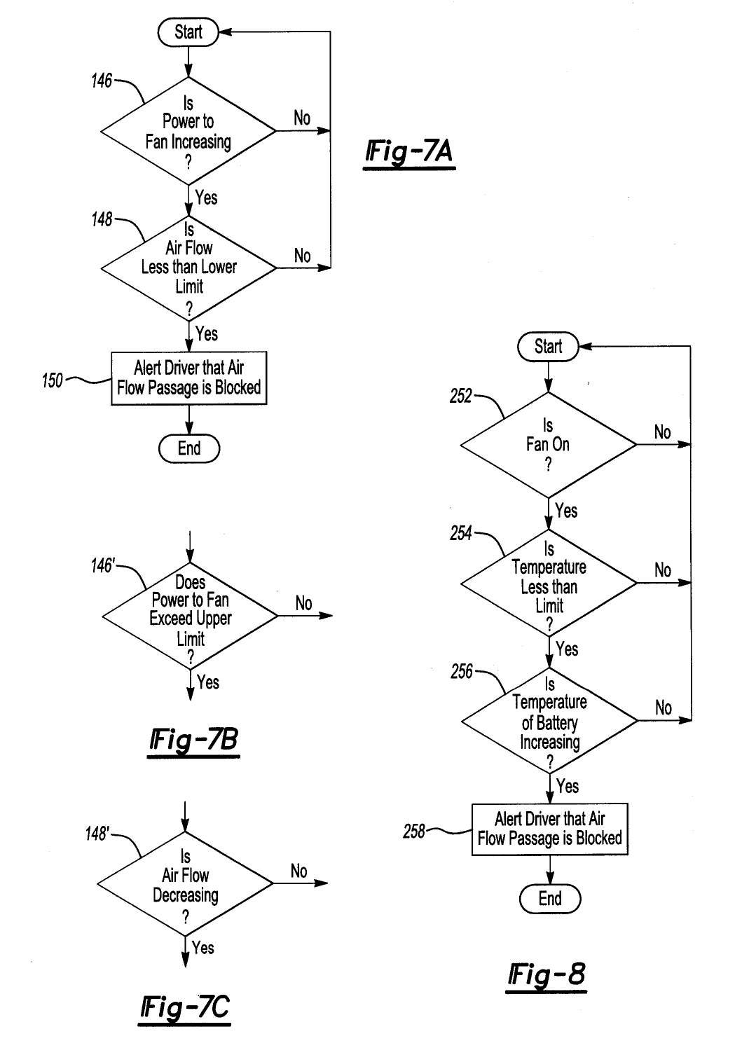

FIG. 7A is a flow chart of a method for determining whether the airflow passage of FIG. 2 is blocked. At 146, controller 130 determines whether the power to fan 126 is increasing. If no, the method loops back to Start. If yes, at 148, controller 130 determines whether the air flow is less than a lower limit, e.g., 100 feet³/min. If no, the method loops back to Start. If yes, at 150, controller 130 alerts the driver that the airflow passage is blocked via display 132.

FIG. 7B is a flow chart of an alternative step of the method of FIG. 7A. At 146′, controller 130 determines whether the power to fan 126 exceeds an upper limit, e.g., 50 W. If no, the method loops back to Start. If yes, the method continues to 148.

FIG. 7C is another flow chart of an alternative step of the method of FIG. 7A. At 148′, controller 130 determines whether the airflow is decreasing. If no, the method loops back to Start. If yes, the method continues to 150.

FIG. 8 is a flow chart of a method for determining whether the airflow passage of FIG. 3 is blocked. At 252, controller 230 determines whether fan 226 is on. If no, the method loops back to Start. If yes, at 254, controller 230 determines if the air temperature in the air passageway is less than a limit, e.g., 20° C. If no, the method loops back to Start. If yes, at 256, controller 230 determines if the temperature of high voltage battery 212 is increasing. If no, the method loops back to Start. If yes, at 258, controller 230 alerts the driver that the airflow passage is blocked via display 232.

The steps of the flow charts above are shown in series. Some or all the steps, however, maybe performed in parallel. For example, 252, 254, 25l may be performed simultaneously by controller 230. A respective flag associated with each step may be set to 1 if the outcome of that step is yes. Controller 230 may then perform 258 if it determines that the flags associated with the respective steps are all 1. Other implementations are also possible. The methods described herein are, of course, applicable for determining whether inlet, outlet, and other air passageways are blocked.

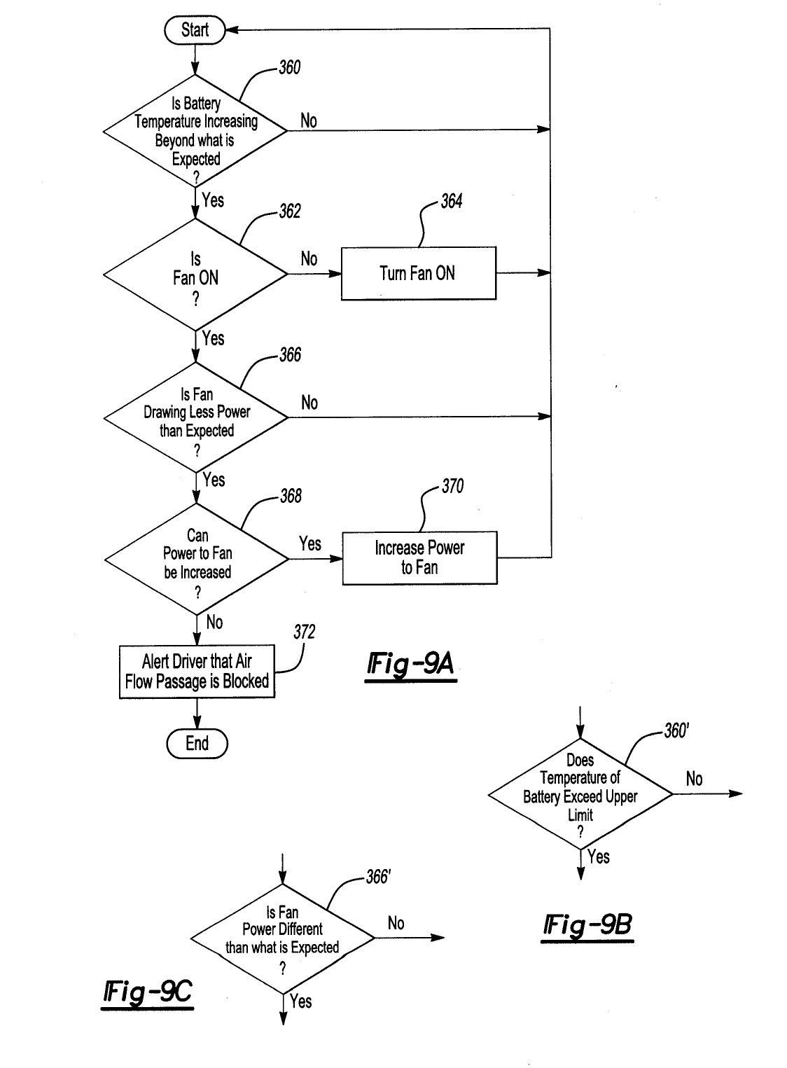

FIG. 9A is a flow chart of a method for determining if an air passage is at least partially blocked. At 360, it is determined whether a battery temperature is increasing beyond what is expected given the operating conditions of a vehicle. If no, the method loops back to Start. If yes, at 362, it is determined whether a fan is on. If no, at 364, the fan is turned on and the method loops back to Start. If yes, the airflow may be insufficient due to a blockage. At 366, It is determined if the fan is drawing less power than expected, e.g., did current to fan drop? If no, the method loops back to Start. If yes, blocked air flow is causing a lower load on the fan. At 368, it is determined whether the power to the fan can be increased. If yes, the power to the fan is increased, e.g., the pulse width modulated voltage is increased. If no, the power to the fan has reached its maximum level allowed. At 372, a driver is alerted that the air flow passage is blocked.

FIG. 9B is a flow chart of an alternative portion of the method of FIG. 9A. At 360′, it is determined if the temperature of the battery exceeds its upper limit. If no, the method loops back to Start. If yes, the method continues to step 362.

FIG. 9C is another flow chart of an alternative portion of the method of FIG. 9A. At 366′, it is determined if the power to the fan is different than what is expected. If no, the method loops back to Start. If yes, the method continues to step 368.

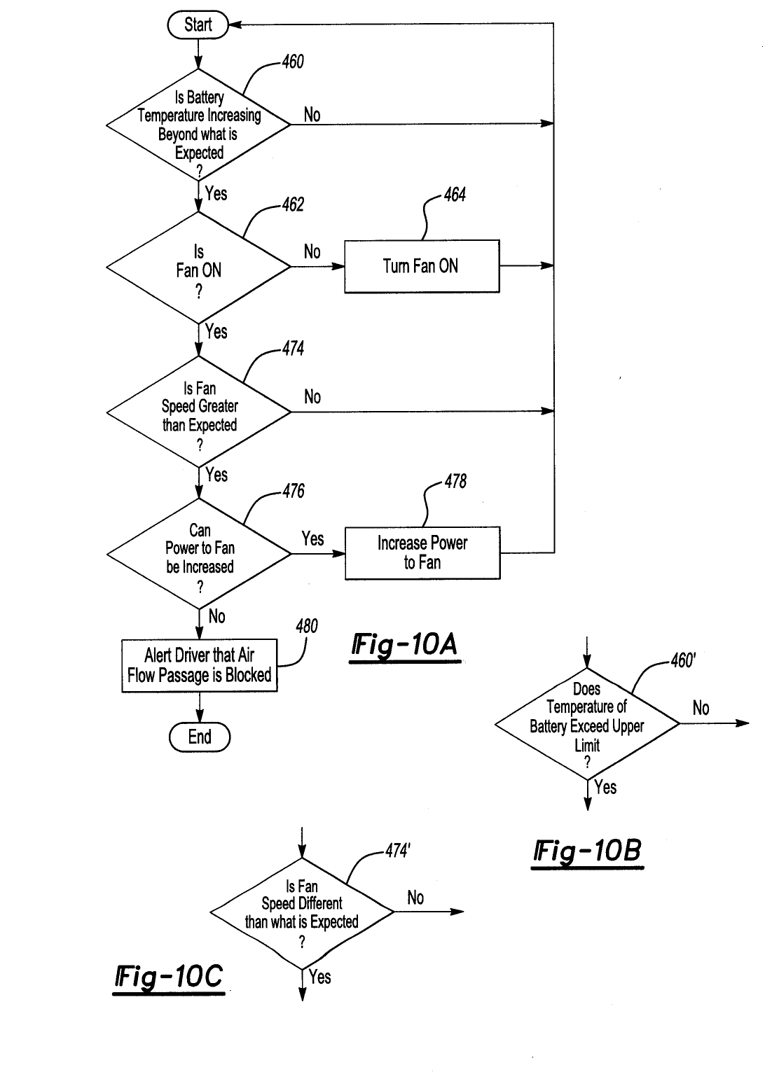

FIG. 10A is another flow chart of a method for determining if an air passage is at least partially blocked. Numbered blocks differing by factors of 100 have similar descriptions, e.g., at 364, 464 the fan is turned on. At 474, it is determined if the fan speed is greater than expected. If no, the method loops back to Start. If yes, blocked air flow is causing a lower load on the fan. At 476, it is determined if the power to the fan can be increased. If yes, at 478, the power to the fan is increased and the method loops back to Start. If no, the power to the fan has reached its maximum level allowed. At 480, a driver is alerted that the air flow passage is blocked.

FIG. 10B is a flow chart of an alternative portion of the method of FIG. 10A.

FIG. 10C is another flow chart of an alternative portion of the method of FIG. 10A. At 474′, it is determined if the fan speed is different than what is expected. If no, the method loops back to Start. If yes, the method continues to step 476.

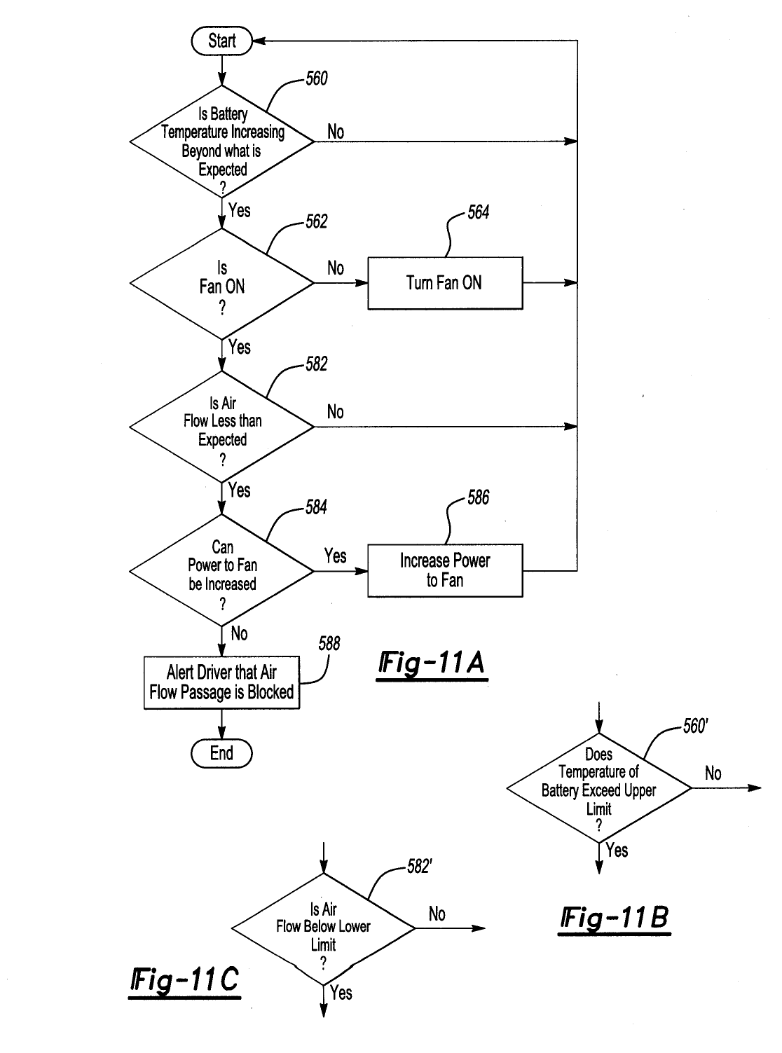

FIG. 11A is still another flow chart of a method for determining if an air passage is at least partially blocked. At 582, it is determined whether the air flow is less than expected. If no, the method loops back to Start. If yes, blocked air flow is causing a lower load on the fan. At 584, it is determined if power to the fan can be increased. If yes, At 586, the power to the fan is increased and the method loops back to Start. If no, the power to the fan has reached its maximum level allowed. At 588, a driver is alerted that the air flow passage is blocked.

FIG. 11B is a flow chart of an alternative portion of the method of FIG. 11A.

FIG. 11C is another flow chart of an alternative portion of the method of FIG. 11A. At 582′, it is determined if the air flow is below a lower limit. If no, the method loops back to Start. If yes, the method continues to step 584.

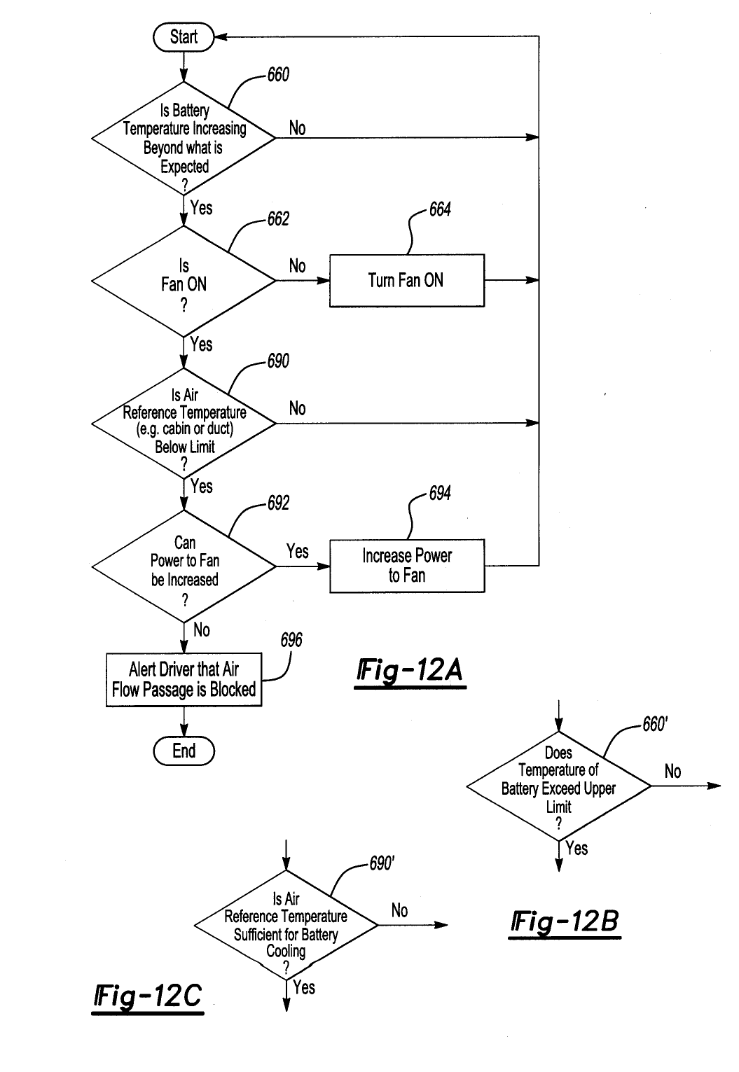

FIG. 12A is still yet another flow chart of a method for determining if an air passage is at least partially blocked. At 690, it is determined if the air reference temperature, e.g., cabin air, is below a lower limit. If no, the method loops back to Start. If yes, the airflow may be insufficient due to a blockage. At 692, it is determined if the power to the fan can be increased. If yes, at 694, the power to the fan is increased and the method loops back to Start. If no, the power to the fan has reached its maximum level allowed. At 696, a driver is alerted that the air flow passage is blocked.

FIG. 12B is a flow chart of an alternative portion of the method of FIG. 12A.

FIG. 12C is another flow chart of an alternative portion of the method of FIG. 12A. At 690′, it is determined if the air reference temperature is sufficient for battery cooling. If no, the method loops back to Start. If yes, the method continues to step 692.

The limits, thresholds, and expected values for the various parameters employed by the above methods may depend on the particular configuration in which the methods are implemented. Testing may be performed to determine the limits, thresholds, and expected values for the parameters for a given configuration.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed:

1. A method for determining, in a vehicle including a power storage unit, an air flow passage to the power storage unit, and a fan to move air in the air flow passage, if the air flow passage is at least partially blocked, the method comprising:
determining a power to the fan;
determining a temperature of the power storage unit;
determining if the air flow passage is at least partially blocked based on the power to the fan and the temperature of the power storage unit; and
indicating that the air flow passage is at least partially blocked if it is determined that the air flow passage is at least partially blocked.

2. The method of claim 1 further comprising determining a speed of the fan.

3. The method of claim 1 wherein the step of determining if the air flow passage is at least partially blocked includes determining if the temperature of the power storage unit is increasing.

4. The method of claim 1 wherein the step of determining a power to the fan comprises determining a voltage supplied to the fan.

5. The method of claim 1 wherein the step of determining if the air flow passage is at least partially blocked includes determining if the temperature of the power storage unit exceeds a predetermined threshold.

6. The method of claim 1 wherein the step of determining if the air flow passage is at least partially blocked includes at least one of determining if the power to the fan is increasing and determining if the power to the fan exceeds a predetermined threshold.

7. The method of claim 1 wherein the step of determining a power to the fan comprises determining a current to the fan.

8. A method for determining, in a vehicle including a power storage unit, an air flow passage to the power storage unit, and a fan to move air in the air flow passage, if the air flow passage is at least partially blocked, the method comprising:
determining a power to the fan;
determining at least one of an air flow and an air pressure in the air flow passage;
determining if the air flow passage is at least partially blocked based on the power to the fan and the at least one of air flow and air pressure in the air flow passage; and
indicating that the air flow passage is at least partially blocked if it is determined that the air flow passage is at least partially blocked.

9. The method of claim 8 wherein the step of determining if the air flow passage is at least partially blocked includes determining if the power to the fan is changing.

10. The method of claim 8 wherein the step of determining if the air flow passage is at least partially blocked includes determining if the power to the fan is increasing.

11. The method of claim 8 wherein the step of determining a power to the fan comprises determining a voltage supplied to the fan.

12. The method of claim 8 wherein the step of determining if the air flow passage is at least partially blocked includes determining if the power to the fan exceeds a predetermined threshold.

13. The method of claim 8 wherein the step of determining if the air flow passage is at least partially blocked includes determining if the at least one of air flow and air pressure in the air flow passage is decreasing.

14. The method of claim 8 wherein the step of determining if the air flow passage is at least partially blocked includes determining if the at least one of air flow and air pressure in the air flow passage is less than a predetermined threshold.

15. A method for determining, in a vehicle including a power storage unit, an air flow passage to the power storage unit, and a fan to move air in the air flow passage, if the air flow passage is at least partially blocked, the method comprising:
determining an on/off state of the fan;
determining a temperature of air in the air flow passage;
determining a temperature of the power storage unit;
determining if the air flow passage is at least partially blocked based on the on/off state of the fan, the temperature of the air in the air flow passage, and the temperature of the power storage unit; and
indicating that the air flow passage is at least partially blocked if it is determined that the air flow passage is at least partially blocked.

16. The method of claim 15 wherein the step of determining if the air flow passage is at least partially blocked includes determining if the temperature of the air in the air flow passage is less than a predetermined threshold.

17. The method of claim 15 wherein the step of determining if the air flow passage is at least partially blocked includes determining if the temperature of the power storage unit is changing.

18. The method of claim 15 wherein the step of determining if the air flow passage is at least partially blocked includes determining if the temperature of the power storage unit is increasing.

19. The method of claim 15 wherein the step of determining if the air flow passage is at least partially blocked includes determining if the temperature of the power storage unit is decreasing.

20. The method of claim 15 wherein the step of determining if the air flow passage is at least partially blocked includes determining if the temperature of the power storage unit exceeds a predetermined threshold.
